(19) United States
(12) Patent Application Publication
(10) Pub. No.: US 2005/0044521 A1
(43) Pub. Date: Feb. 24, 2005

(54) Method and system for determining constraints for a printed circuit board design module

(76) Inventor: John Malvern Swope, Sacrament, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/643,665

(22) Filed: Aug. 19, 2003

(51) Int. Cl. H03K 17/693; G06F 17/50

(52) U.S. Cl. 716/15; 716/1

(57) ABSTRACT

A method for generating a printed circuit board design module is provided. The method includes compiling information that is usable to derive one of more low level details associated with a printed circuit board, determining one or more high level constraints that are usable with the information to generate the low level details, and generating the printed circuit board design module such that the printed circuit board design module includes the information and such that the printed circuit board design module is configured to receive the one or more high level constraints.

### FIELD OF THE INVENTION

The present invention generally relates to the design of printed circuit boards, and more particularly, to a method and system for determining constraints for a printed circuit board design module.

### BACKGROUND OF THE INVENTION

A printed circuit board (PCB) is typically a thin plate on which chips and other electronic components are placed. Computers generally include one or more PCBs which are often called cards or adapters. Schematics are used by PCB designers in the PCB design process to illustrate the connections of the electrical circuits to be placed on the board. PCB designers often consider numerous design constraints correlated to the schematics in order to produce a workable PCB design.

In order to convert schematics into a finished PCB layout, a process is undertaken which involves steps such as: (1) determining routing rules given impedance requirements and signal integrity issues (such as signal speed, maximum allowable cross-talk, etc.), (2) determining a board stack up arrangement based on the numerous mechanical and electrical constraints that are presented, (3) determining an acceptable component placement scheme given known interconnection and mechanical constraints, (4) determining a trace routing scheme (often thousands of traces) to connect components that have already been placed (in complex designs this often must be done manually because the computer doesn't have a means of understanding the numerous constraints that are involved), (5) running DRCs (design rule checks) to detect any mistakes present in the PCB design, and (6) iterating through the above noted steps until a workable PCB layout is achieved. These steps represent only a partial listing of the steps involved in the process that translates schematics into actual hardware. The steps, however, highlight the complex and time consuming task involved in PCB design.

Automated printed circuit board design software such as auto-routing software typically operates using algorithm-specific variables provided by a user. Unfortunately, these variables may be difficult or impossible for a user to calculate prior to providing them to the software. Rather, a user often uses his or her instincts or experience to derive starting point variables and then iteratively modifies the variables with each design iteration provided by the software. This process is generally inefficient for the user. Accordingly, there is a continuing need to make printed circuit board design processes more efficient.

### SUMMARY OF THE INVENTION

The present disclosure provides a method for generating a printed circuit board design module. The method includes compiling information that is usable to derive one of more low level details associated with a printed circuit board, determining one or more high level constraints that are usable with the information to generate the low level details, and generating the printed circuit board design module such that the printed circuit board design module includes the information and such that the printed circuit board design module is configured to receive the one or more high level constraints.

### BRIEF DESCRIPTION OF THE DRAWINGS

FIG. 1 is a flow chart illustrating an embodiment of a method for determining constraints for a printed circuit board design module.

FIG. 2 is a diagram illustrating an embodiment of a system for determining constraints for a printed circuit board design module.

FIG. 3a is a chart containing a partial listing of high level mechanical constraints according to one embodiment.

FIG. 3b is a chart containing a partial listing of high level electrical constraints according to one embodiment.

FIG. 3c is a chart containing a partial listing of high level cost constraints according to one embodiment.

FIG. 4 is a flow chart illustrating an embodiment of a method for using a printed circuit board design module.

FIG. 5 is a diagram illustrating an embodiment of a system for using a printed circuit board design module.

FIG. 6 is a diagram illustrating an embodiment of a printed circuit board design module.

FIG. 7 is diagram illustrating an embodiment of a printed circuit board stack up scheme.

### DETAILED DESCRIPTION

In the following detailed description of the preferred embodiments, reference is made to the accompanying drawings which form a part hereof, and in which is shown by way of illustration specific embodiments in which the invention may be practiced. It is to be understood that other embodiments may be utilized and structural or logical changes may be made without departing from the scope of the present invention. The following detailed description, therefore, is not to be taken in a limiting sense, and the scope of the present invention is defined by the appended claims.

As described herein, a printed circuit board (PCB) design module is configured to receive high level constraints associated with a desired PCB from a user and generate low level details that comprise a printed circuit board design. The desired printed circuit board may be manufactured in accordance with the printed circuit board design.

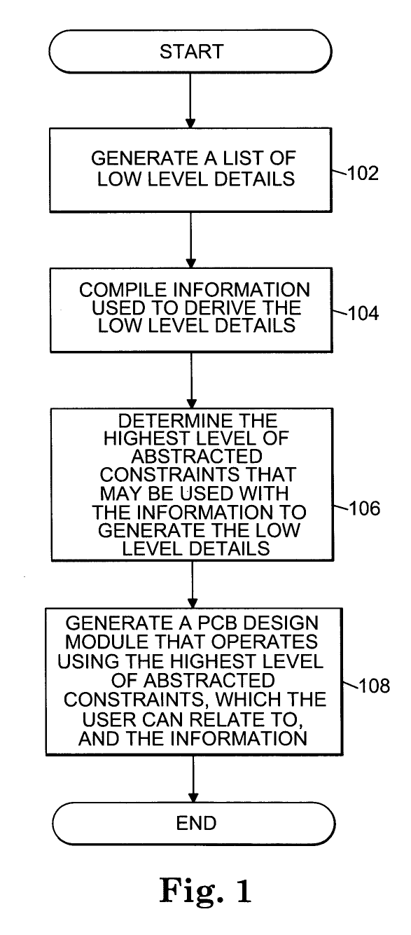

FIG. 1 is a flowchart illustrating an embodiment of a method for determining constraints for a printed circuit board design module. In FIG. 1, a list of low level details associated with a printed circuit board design layout is generated as indicated in a block 102. The low level details include implementation details such as routing details, component placement details, and/or stack up details. Examples of such low level details include trace width and trace spacing. Low level details could also include variables that are necessary for a specific software algorithm, but may not directly relate to the physical design.

Information used to derive the low level details is compiled as indicated in a block 104. The information may include mathematical equations that are useable to calculate the low level details, tables such as industry rule-of-thumb tables that are usable to determine the low level details, or other types of information that is used to determine the low level details.

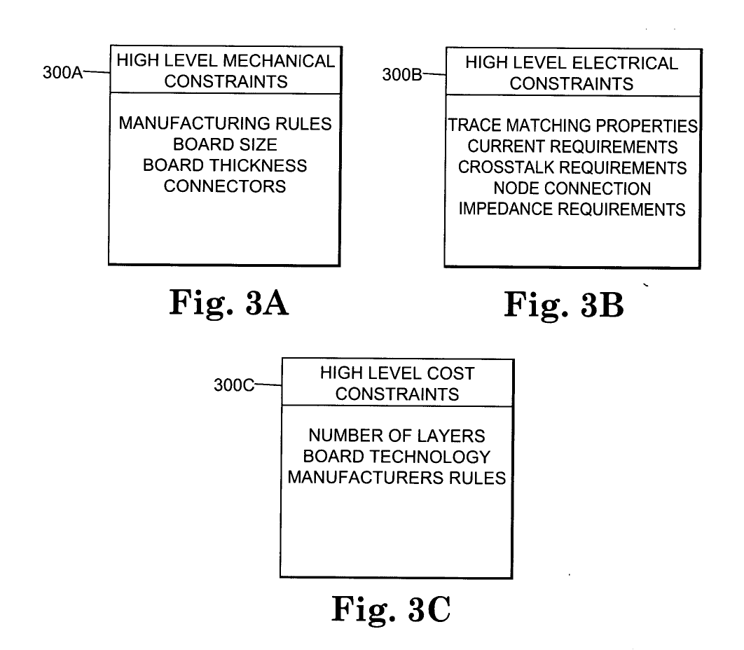

The highest level of abstracted constraints that may be used with the information to generate the low level details is determined as indicated in a block 106. These high level constraints may include schematic constraints, electrical constraints, mechanical constraints, and/or cost constraints. Examples of high level constraints are illustrated in FIGS. 3a, 3b, and 3c and described in additional detail below.

A printed circuit board design module that operates using the highest level of abstracted constraints, which the user can relate to, and the information is generated as indicated in a block 108. The printed circuit board design module includes the information and is configured to receive the high level constraints from a user.

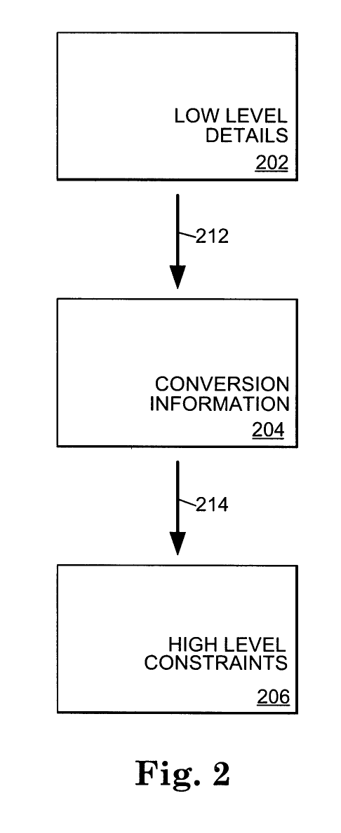

FIG. 2 is a diagram illustrating an embodiment of a system for determining constraints for a printed circuit board design module. FIG. 2 includes low level details 202, conversion information 204, and high level constraints 206. After a list of low level details 202 is generated, conversion information associated with the low level details is gathered as indicated by an arrow 212. After the conversion information 204 is gathered, the high level constraints 206 are determined using the conversion information as indicated by an arrow 214.

FIG. 3A illustrates one embodiment of a chart 300A that includes a partial listing of high level mechanical constraints. High level mechanical constraints include, but are not limited to, manufacturing rules, board size, board thickness, and connections. According to exemplary embodiments, these constraints may be “front loaded” as the system is able to understand the constraints and translate or convert them into low level design details.

FIG. 3B illustrates one embodiment of a chart 300B that includes a partial listing of high level electrical constraints. High level electrical constraints include, but are not limited to, trace matching properties, current requirements, crosstalk requirements, node connection, and impedance requirements. According to exemplary embodiments, these constraints may be “front loaded” as the system is able to understand the constraints and translate or convert them into low level design details.

FIG. 3C illustrates one embodiment of a chart 300C that includes a partial listing of high level cost constraints. High level cost constraints may include, but are not limited to, a number of layers, a board technology, and to what extent manufacturing guidelines are followed. According to exemplary embodiments, these constraints may be “front loaded” as the system is able to understand the constraints and translate or convert them into low level design details.

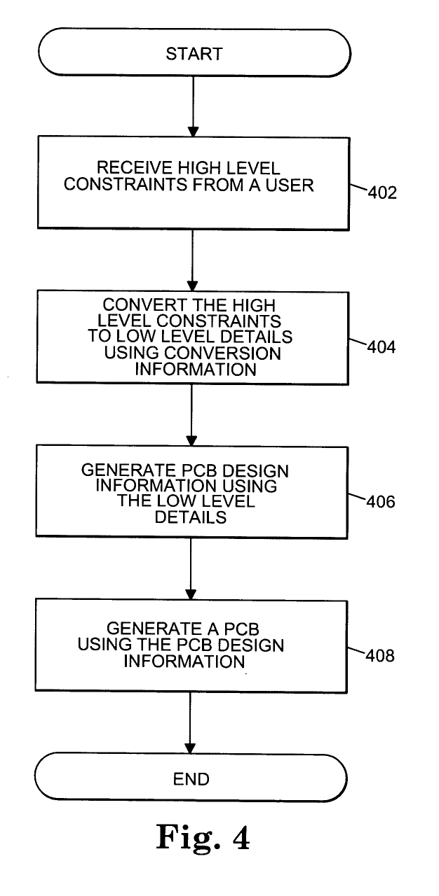

FIG. 4 is a flow chart illustrating an embodiment of a method for using a printed circuit board design module. In FIG. 4, high level constraints are received from a user by the printed circuit board design module as indicated in a block 402. The high level constraints are converted by the printed circuit board design module to low level details using the conversion information as indicated in a block 404. The conversion process converts the low level details into a format that is usable by algorithms in the printed circuit board design module. PCB design information is generated using the low level details as indicated as indicated in a block 406. A printed circuit board is generated using the PCB design information as indicated in a block 408.

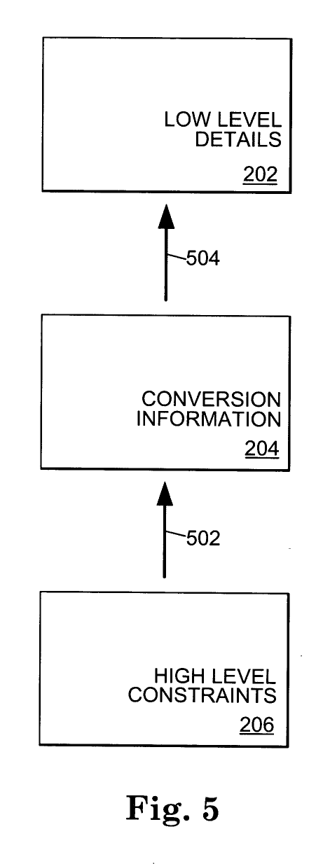

FIG. 5 is a diagram illustrating an embodiment of a system for using a printed circuit board design module. FIG. 5 shows low level details 202, conversion information 204, and high level constraints 206 from FIG. 2. In response to high level constraints 206 being received from a user as indicated in block 402 in FIG. 4, they are combined with conversion information 204, as indicated by an arrow 502, to produce low level details 202 in a format that is usable by algorithms in the printed circuit board design module as indicated by an arrow 504.

Additional details of generating printed circuit board design information may be found in U.S. patent application Ser. No. 10/193,623, entitled Method and System for Automated Design of Printed Circuit Boards, and listing John M. Swope as inventor.

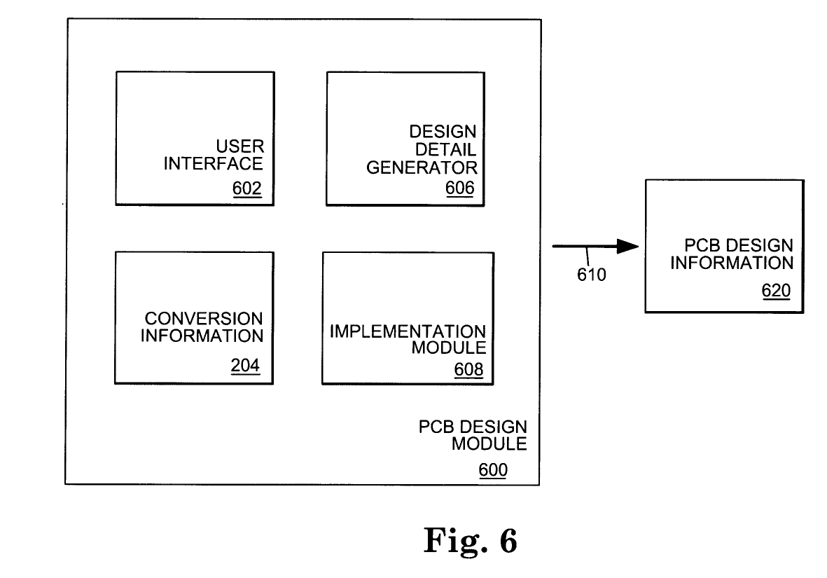

FIG. 6 is a diagram illustrating an embodiment of a printed circuit board design module. In FIG. 6, printed circuit board design module 600 includes a user interface 602, conversion information 204, a design detail generator 606, and an implementation module 608. In response to receiving high level constraints 206, printed circuit board design module 600 generates printed circuit board design information 620 as indicated by an arrow 610.

User interface 602 is executable by a computer system to cause high level constraints and other information to be received from a user. User interface 602 provides the high level constraints to design detail generator 606. High level constraints may also be provided to design detail generator 606 in other ways. For example, user interface 602 may be incorporated into a schematic software tool (not shown) so that a user does not have to manually enter the constraints into printed circuit board design module 600.

Design detail generator 606 accesses the high level constraints and conversion information 204. Design detail generator 606 generates the low level details using the high level constraints and conversion information 204 and provides the low level details to implementation module 608.

Implementation module 608 implements a design that complies with the high level constraints provided by the user using the low level details generated by design detail generator 606. Implementation module 608 generates a PCB design according to the low level details and stores the design as PCB design information 620.

PCB design module 600 may include other components not shown in FIG. 6.

PCB design module 600 may include software, hardware, or a combination of software and hardware and may be stored in any type of portable or non-portable computer readable medium or media.

The use of PCB design module 600 may be seen with reference to the following example. In this example, 100 nets are desired to be connected between two chips. In order for the circuit to work properly, the traces need to be routed with an impedance of 50 Ohms, the traces need to have less than 10% crosstalk, the traces need to be less than 10 inches in length, and the traces need to be length matched within 50 pS.

Thus, a user provides the following high level constraints to PCB design module 600.
Cross-talk<10%;
Impedance=50 Ohms;
Trace length<10 inches;
Trace lengths matched within 50 pS; and
Losses<15% at 200 MHz

The user also provides PCB design module 600 with a table associated with the manufacturing process such as Table 1 below. The table indicates that in this manufacturing process, the following information is true.

TABLE 1

| | | | | |
|---|---|---|---|---|
| Layer 1: | 6 mil | -> | 50 Ohms | Propagation delay = 179 pS/inch |
| | 8 mil | -> | 35 Ohms | |
| Layer 2: | 6 mil | -> | 60 Ohms | Propagation delay = 179 pS/inch |
| | 8 mil | -> | 50 Ohms | |

Using the high level constraints and the table, PCB design module 600 generates PCB design information 620 which includes the low level details that may be used to manufacture a PCB. For example, PCB design module 600 determines the effects of trace spacing on crosstalk. In particular, PCB design module 600 may determine that traces may be 5 mils apart over a distance of 6 inches, 25 mils apart over a distance of 4 inches, or 10 mils apart over a distance of 2 inches. Further, PCB design module 600 determines that the trace widths should be 6 mils on layer 1 and 8 mils on layer 2 to meet the 50 Ohm impedance requirement using the table.

In addition, PCB design module 600 determines that trace lengths must be within 0.3 inches of one another for straight lines given the manufacturing propagation delays. PCB design module 600 may use equations to determine propagation skew around corners for traces that include turns.

PCB design module 600 also calculates the Skin Effect Resistance given the operating frequency supplied by the user and the geometry of the traces determined by PCB design module 600 to ensure that losses are kept within user-specified limits.

From high level constraints c and d above, PCB design module 600 further determines that all traces may be 7 inches or 8 inches, for example, but that the traces may not be a combination of 7 inch traces and 8 inch traces and the traces may not be 11 inches.

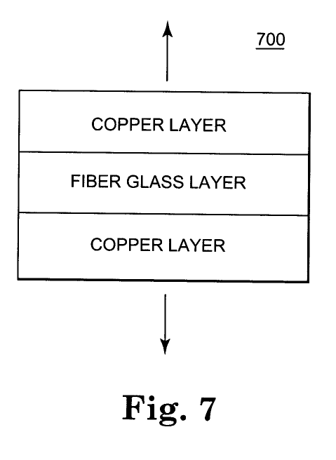

FIG. 7 illustrates an embodiment of a general stack-up scheme 700. Stack-up scheme 700 includes copper layers 701, fiberglass layer 703 and copper layers 705. Stack-up scheme 700 may employ several layers of interleaved copper and fiberglass layers. Because such complex stack-ups may involve significant cost overhead, an objective of one embodiment of the present invention may be to provide an optimal stack-up arrangement given the provided design constraints.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the chemical, mechanical, electromechanical, electrical, and computer arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

1. A method for generating a printed circuit board design module comprising:
compiling information that is usable to derive one of more low level details associated with a printed circuit board;
determining one or more high level constraints that are usable with the information to generate the low level details; and
generating the printed circuit board design module such that the printed circuit board design module includes the information and such that the printed circuit board design module is configured to receive the one or more high level constraints.

2. The method of claim 1 further comprising:
generating a list of the low level details prior to compiling the information.

3. The method of claim 1 wherein the high level constraints include schematic constraints.

4. The method of claim 1 wherein the high level constraints include electrical constraints.

5. The method of claim 1 wherein the high level constraints include mechanical constraints.

6. The method of claim 1 wherein the high level constraints include cost constraints.

7. The method of claim 1 wherein the low level details include routing details.

8. The method of claim 1 wherein the low level details include component placement details.

9. The method of claim 1 wherein the low level details include stack-up details.

10. The method of claim 1 wherein the information includes mathematical equations usable to calculate the low level details using the high level constraints.

11. The method of claim 1 wherein the information includes a table usable to determine the low level details using the high level constraints.

12. The method of claim 1 further comprising:
generating the printed circuit board design module such that the printed circuit board design module is configured to receive the one or more high level constraints from a user interface incorporated into a schematic software tool.

13. A computer system comprising:
a processor; and
a memory that includes a printed circuit board design module that is executable by the processor, the printed circuit board design module being generated by:
compiling information that is usable to derive one of more low level details associated with a printed circuit board;
determining one or more high level constraints that are usable with the information to generate the low level details; and
generating the printed circuit board design module such that the printed circuit board design module includes the information and such that the printed circuit board design module is configured to receive the one or more high level constraints.

14. The computer system of claim 13 wherein the information includes mathematical equations usable to calculate the low level details using the high level constraints.

15. The computer system of claim 13 wherein the information includes a table usable to determine the low level details using the high level constraints.

16. The computer system of claim 13 wherein the high level constraints are selected from the group consisting of schematic constraints, electrical constraints, and mechanical constraints.

17. The computer system of claim 13 wherein the low level details are selected from the group consisting of routing details, component placement details, and stack up details.

18. A computer-readable medium storing a printed circuit board design module executable by a computer system, where the printed circuit board design module is generated by:
compiling information that is usable to derive one of more low level details associated with a printed circuit board;
determining one or more high level constraints that are usable with the information to generate the low level details; and
generating the printed circuit board design module such that the printed circuit board design module includes the information and such that the printed circuit board design module is configured to receive the one or more high level constraints.

19. The computer-readable medium of claim 18 wherein the information includes mathematical equations usable to calculate the low level details using the high level constraints.

20. The computer-readable medium of claim 18 wherein the information includes a table usable to determine the low level details using the high level constraints.

21. The computer-readable medium of claim 18 wherein the high level constraints are selected from the group consisting of schematic constraints, electrical constraints, and mechanical constraints.

22. The computer-readable medium of claim 18 wherein the low level details are selected from the group consisting of routing details, component placement details, and stack up details.
